(19) United States
(12) Patent Application Publication
(10) Pub. No.: US 2005/0092233 A1
(43) Pub. Date: May 5, 2005

(54) Single and multi-layer crystalline structures

(76) Inventor: Tyler Sims, Knoxville, TN (US)

Correspondence Address: AGILENT TECHNOLOGIES, INC.;Legal Department, DL 429, Intellectual Property Administration, P.O. Box 7599, Loveland, CO, 80537-0599, US

(21) Appl. No.: 10/702,016

(22) Filed: Nov. 5, 2003

(51) Int. Cl. C30B 23/00; C30B 25/00; C30B 28/12; C30B 28/14

(52) U.S. Cl. 117/89

(57) ABSTRACT

An opto-fluidic device includes a logic and heater layer placed on a top of a substrate layer. The logic and heater layer includes both a logic circuitry region and a heater region. The heater region includes a resistor used as a heater. A liquid containment region is located below the substrate layer. The liquid containment region includes a trench that is situated below the heater region so that the heater can be used to heat liquid contained within the trench.

### BACKGROUND

The present invention relates to components useful in optical switching devices and pertains particularly to single and multi-layer crystalline structures.

Optical fibers provide significantly higher data rates than electronic paths. However, effective utilization of the greater bandwidth inherent in optical signal paths requires optical cross-connect switches.

One type of optical cross-connect switch utilizes total internal reflection (TIR) switching elements. A TIR element consists of a waveguide with a switchable boundary. Light strikes the boundary at an angle. In the first state, the boundary separates two regions having substantially different indices of refraction. In this state the light is reflected off of the boundary and thus changes direction. In the second state, the two regions separated by the boundary have the same index of refraction and the light continues in a straight line through the boundary. The magnitude of the change of direction depends on the difference in the index of refraction of the two regions. To obtain a large change in direction, the region behind the boundary must be switchable between an index of refraction equal to that of the waveguide and an index of refraction that differs markedly from that of the waveguide.

One type of TIR element is taught in U.S. Pat. No. 5,699,462 which is hereby incorporated by reference. The TIR element taught in this patent utilizes thermal activation to displace liquid from a gap at the intersection of a first optical waveguide and a second optical waveguide. In this type of TIR, a trench is cut through a waveguide. The trench is filled with an index-matching liquid. A bubble is generated at the cross-point by heating the index matching liquid with a localized heater. The bubble must be removed from the crosspoint to switch the cross-point from the reflecting to the transmitting state and thus change the direction of the output optical signal. Efficient operation of such a TIR element requires effective placement and operation of heating devices within and around the TIR elements.

### SUMMARY OF THE INVENTION

In accordance with a preferred embodiment of the present invention, an opto-fluidic device includes a logic and heater layer placed on a top of a substrate layer. The logic and heater layer includes both a logic circuitry region and a heater region. The heater region includes a resistor used as a heater. A liquid containment region is located below the substrate layer. The liquid containment region includes a trench that is situated below the heater region so that the heater can be used to heat liquid contained within the trench.

### BRIEF DESCRIPTION OF THE DRAWINGS

FIG. 1A, 1B, 1C, 1D and 1E illustrate a process for forming a resistor and/or logic from the same single crystalline substrate.

FIG. 2 and FIG. 3 show examples of multiple layer resistors formed in accordance with preferred embodiments of the present invention.

FIGS. 4A, 4B and 4C show an example of a total internal reflection (TIR) switching element in accordance with a preferred embodiment of the present invention.

FIGS. 5A, 5B and 5C illustrate other embodiments of a TIR switching element in accordance with preferred embodiments of the present invention.

FIGS. 6A, 6B and 6C show another example of a TIR in accordance with another preferred embodiment of the present invention.

FIGS. 7A and 7B show another example of a TIR in accordance with another preferred embodiment of the present invention.

FIGS. 8A, 8B, 8C, 8D, 8E, 8F and 8G illustrate construction of a fully integrated thermal optical crossconnect switch in accordance with another preferred embodiment of the present invention.

FIG. 9 shows a fully integrated thermal optical crossconnect switch in accordance with another preferred embodiment of the present invention.

### DESCRIPTION OF THE PREFERRED EMBODIMENT

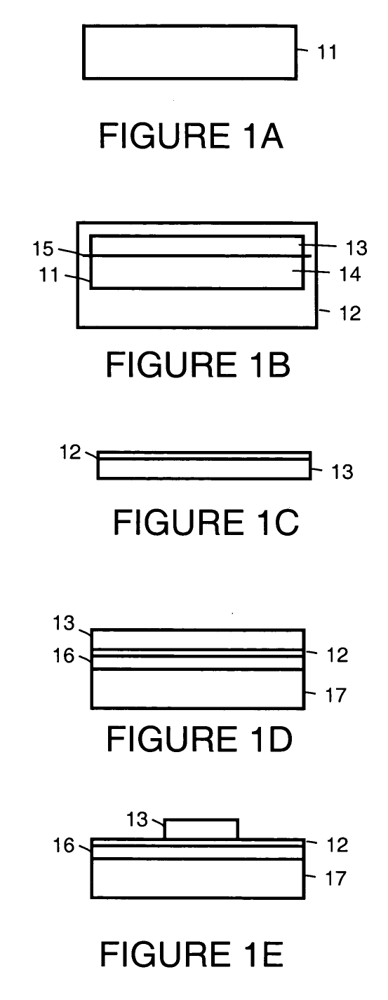

FIGS. 1A, 1B, 1C, 1D and 1E illustrate a single crystalline process for forming a resistor, logic and a waveguide on a substrate. FIG. 1A shows a substrate 11. For example substrate 11 is composed of silicon, fused silica or silicon carbon (SiC). Alternatively, substrate 11 can consist of another material in the fourth group or fifth group of the periodic table combined with carbon (e.g., HfC, TaC, TiC, ZrC).

FIG. 1B shows substrate 11 after oxidation and an implant to form a cleave plane. For example, oxide 12 is formed by thermal oxidation in a furnace. For example, oxide 12 is formed of SiO₂, ZrO₂, ThO₂, HfO₂, SiCO, SiON, or some other oxide. The implant is, for example, a high energy implant that causes a crystalline fracture plane 15, dividing substrate 11 into an upper substrate region 13 and a lower substrate region 14. See U.S. Pat. No. 6,248,649 B1 for an example of a controlled cleavage process.

FIG. 1C shows upper substrate region 13 having been separated from lower substrate region 14 and polished. The result is substrate region 13 having a thickness of, for example, less than 1 micron to 10 microns. Oxide region 12 has a thickness of, for example, less than 1 micron to 3 microns.

FIG. 1D shows substrate region 13 at oxide region 12 having been bonded to an oxide region 16 of another substrate 17. The bonding is performed, for example, by fusion or anodic bonding.

FIG. 1E shows substrate region 13 having been patterned and etched to form a resistor, logic, waveguide or some other entity. Substrate region 13 is a single crystalline structure. Pattern interconnect layers, deposition metal and passivation are added as needed. Vias may be used as necessary to connect structures formed from substrate region 13 to logic, backside heaters, power and grounds on the other side of substrate 17.

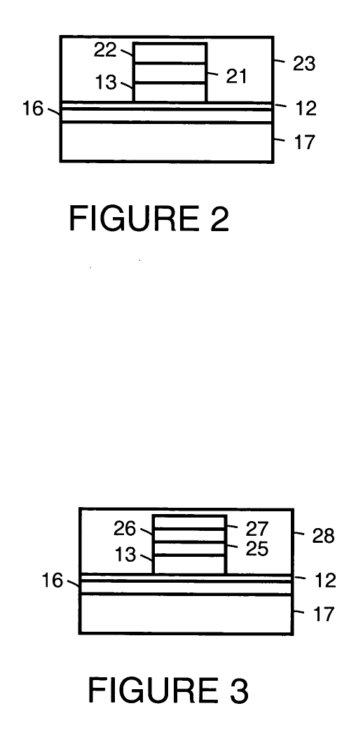

FIG. 2 shows an example of the process illustrated in FIG. 1 being used to form a multi-layer resistor. Additional layers 21 and 22 are formed over substrate region 13. For example layer 21 and layer 22 are deposited layers. Alternatively, layer 21 can be a substrate bonded to substrate region 13 before patterning and etching of substrate region 13. Layer 22 is, for example, an interconnect layer formed of, for example molybdenum (Mo), tungsten (W) or aluminum (Al). The addition of layer 21 allows for the formation of multilayer resistors. Additional layers can be added between layer 21 and layer 22 to increase the number of layers available for resistor formation. An oxide layer 23 protects and isolates circuitry.

Using additional layers as shown in FIG. 2 allows for increased flexibility in the provision of resistors. For example, it allows for tunable resistance via closeness. That is, with many different layers on top of each other the distance across a layer versus the distance through a layer can be tuned so that charge can spread out or be constricted in a 3D region. This allows for the construction of resistors with the smallest average constriction (thickness and dimensional shape), using material with the lowest average resistivity. Different layers can be formed with different resistivities. When different materials are used, the more chemically stable material can be used for a top layer. More thermally conductive material can be used for lower layers. This combination allows the normalizing of heat distributions that can hinder defect creation, while creating a diffusion buffer from oxidation or other chemical reactions.

FIG. 3 is another embodiment where layers 25, 26 and 27 have been formed on layer 13. For example, layers 25, 26 and 27 have been formed using chemical vapor deposition (CVD). Thin combinational multi-layers increase resistivity of the stack, increase the lateral thermal conductivity of the stack and create diffusion barriers with the alternating layers. For example, the deposited stack includes alternative layers of HfC and SiC. HfC is chemically stable and provides good electrical conductivity. SiC provides high heat transfer and is relatively chemically stable but has a much lower electrical conductivity.

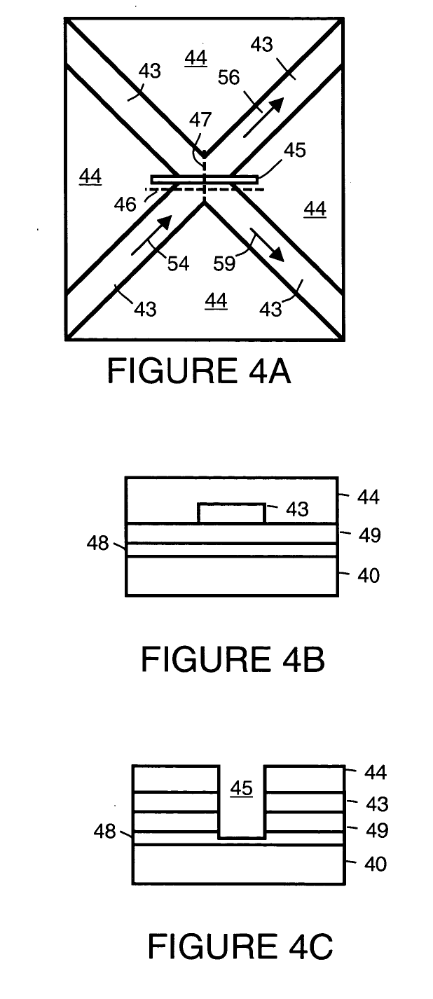

FIGS. 4A, 4B and 4C show an example of a total internal reflection (TIR) switching element made using the process illustrated in FIGS. 1A through 1E.

FIG. 4A is a sliced top view of a TIR cross-connect switch. Light traveling through optical core material 43 in a direction 54 encounters a trench 45. When trench 45 is filled with liquid, the light traveling in a direction continues straight across the trench as illustrated by a direction 56. When there is a bubble within trench 45, the light reflects at the critical angle (˜57 degrees) after encountering trench 45 and goes in a direction 59. Cladding material 44 acts as cladding to optical core 43.

A line 46 indicates a direction of a cross sectional slice shown in FIG. 4B. In FIG. 4B, a substrate 40 corresponds to substrate 17 shown in FIG. 1. An oxide layer 48 corresponds to an oxide layer 16 shown in FIG. 1. An oxide layer 49 corresponds to an oxide layer 12 shown in FIG. 1. Optical core material 43 corresponds to substrate region 13 shown in FIG. 1. Oxide layer 49 acts as cladding material in addition to cladding material 44.

In FIG. 4A, a line 47 indicates a direction of a cross sectional slice shown in FIG. 4C. For example, substrate 40 is composed of silicon, fused silica or silicon carbon (SiC) or some other suitable material. For example, optical core material 43 is composed of TiO₂, GeOx or SiGe. For example, cladding material 44 and oxide layer 48 and oxide layer 49 are composed of oxide (e.g., SiO2).

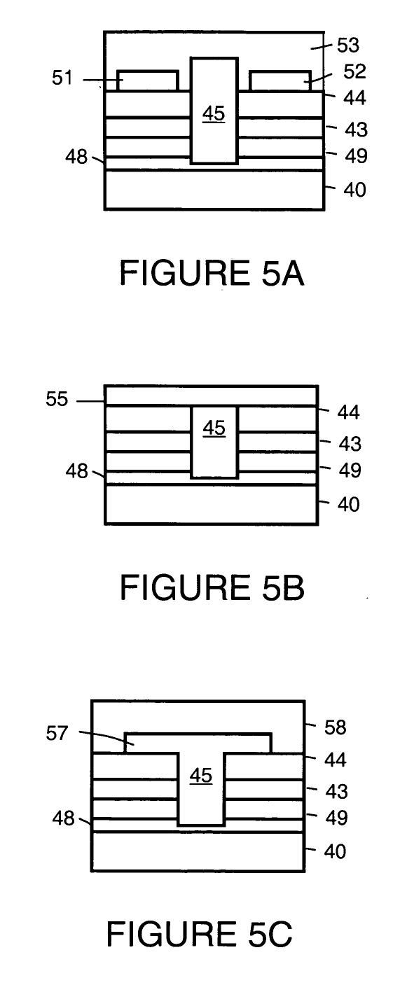

FIGS. 5A, 5B and 5C are cross-sectional slices indicating various caps place over cladding material 44. For example, in FIG. 5A, trench 45 has been enclosed by a cap 53. For example, cap 53 is formed from fused silica. Additional resistive regions 51 and 52 are formed within cap 53. For example, resistive regions 51 and 52 are formed from single crystal materials or low thermal coefficient of expansion (TCE) refractory metals such as doped silicon, tungsten(W) or tantalum (TA).\

In an alternative embodiment shown in FIG. 5B, trench 45 has been enclosed by a cap 55. For example, cap 55 is composed of fused silica.

In an alternative embodiment shown in FIG. 5C, trench 45 has been enclosed by a cap 58. Tube area 57 allows for disbursement of liquid between TIR switching elements.

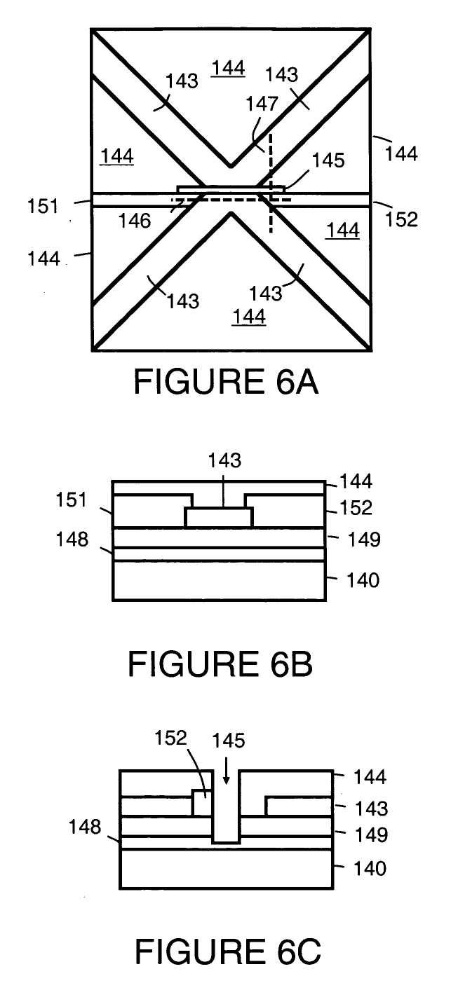

FIGS. 6A, 6B and 6C shows another example of a total internal reflection (TIR) switching element made with the process illustrated in FIG. 1.

FIG. 6A is a sliced top view of a TIR cross-connect switch. Light traveling through optical core material 143 encounters a trench 145. When trench 145 is filled with liquid, the light traveling in a direction continues straight across the trench. When there is a bubble within trench 145, the light reflects at the critical angle(˜57 degrees) after encountering trench 145. Cladding material 144 acts as cladding to optical core 143.

A heating segment 151 and a heating segment 152 are used to provide a source for heating liquid within trench 145. For example, heating segment 151 and heating segment 152 can be composed of a co-sputtered indium tin oxide (ITO) or ZnO and SiO2 mix, or another TCO that is index matched to the cladding materials. Heating segment 151 and heating segment 152 are electrically connected through optical core material 143. This allows optical core material 143 to also act as a heater to heat liquid within trench 145.

A line 146 indicates a direction of a cross sectional slice shown in FIG. 6B. A line 147 indicates a direction of a cross sectional slice shown in FIG. 6C. FIGS. 6B and 6C show a substrate 140, an oxide layer 148, an oxide layer 149, heating segment 151, heating segment 152, optical core material 143 and cladding material 144.

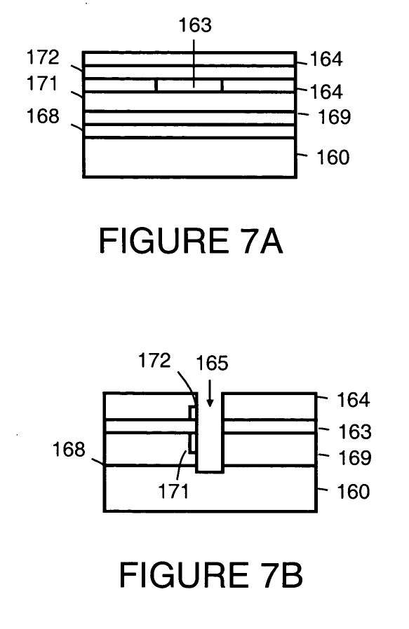

FIGS. 7A and 7B show another example of a total internal reflection (TIR) switching element made with the process illustrated in FIG. 1. FIG. 7A is a first cross-sectional view showing a substrate 160, an oxide layer 168, an oxide layer 169, a heating segment 171, a heating segment 172, optical core material 163 and cladding material 164. FIG. 7B is a second cross-sectional viewing showing a substrate 160, an oxide layer 168, an oxide layer 169, a heating segment 171, a heating segment 172, optical core material 163, cladding material 164 and a trench 165.

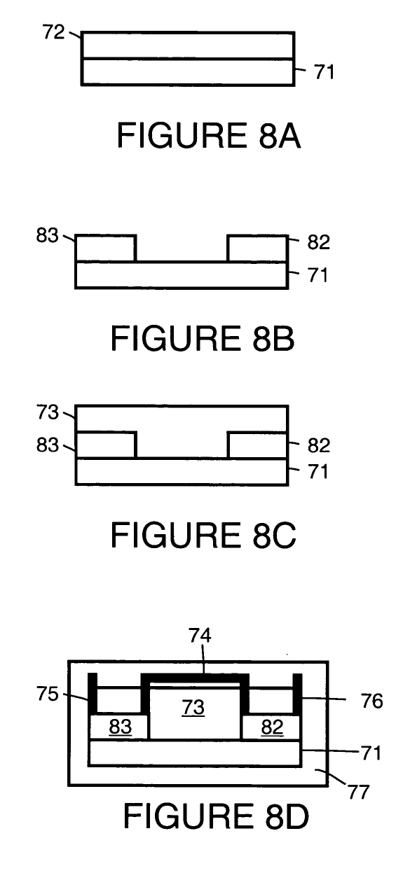

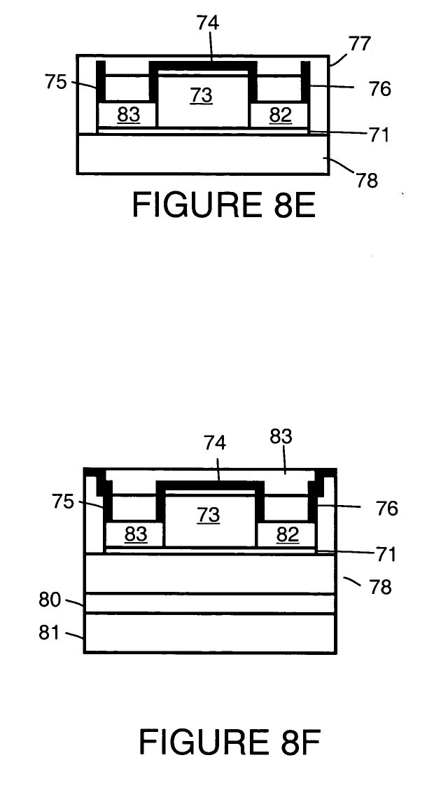

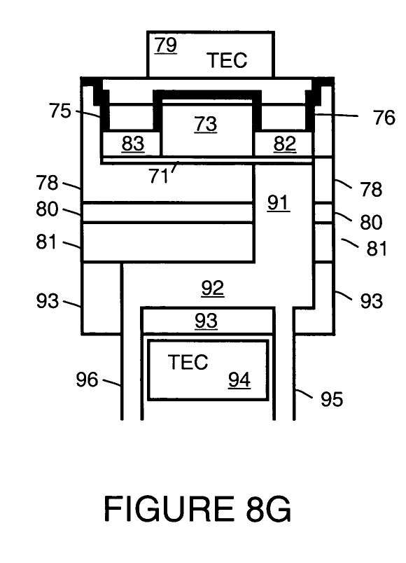

FIGS. 8A, 8B, 8C, 8D, 8E, 8F and 8G illustrate construction of a fully integrated thermal optical crossconnect switch that is a completely hermetically aligned resistor logic with yoked networkable electrofluidicoptics (CHARLYNE).

FIG. 8A, shows a substrate region 71 and an oxide region 72. Substrate region 71 is composed of silicon, fused silica, or silicon carbon (SiC). Alternatively, substrate region 71 can consist of another material in the fourth group or fifth group of the periodic table combined with carbon (e.g., HfC, TaC, TiC, ZrC).

Oxide region 72 is formed by oxidation of a substrate. For example, oxide region 72 consists of SiO2, HFO, SiCO, etc. After oxidation, an implant is made in the substrate to form a cleave plane. Substrate region 71 is separated from the rest of the substrate and polished. For example substrate region 71 has a thickness of, for example, less than 1 micron to 10 microns, and oxide region 12 has a thickness of, for example, less than 1 micron to 3 microns.

FIG. 8B shows logic 83 and resistor 82 being formed in a same layer on substrate region 71. As necessary, redeposition of material can be performed to use a metal multilayer resistor on top of single crystal materials. Resistor 82 can be thinned down, if needed, using a dry etch.

FIG. 8C shows an oxide layer 73, such as TEOS or PSG having been deposited. A chemical mechanical polishing (CMP) is then performed.

FIG. 8D shows formation of connectors 74, 75 and 76 composed, for example, of tungsten, deposited and patterned. An oxide coating 77 is formed, for example by thermal growth. Oxide coating 77 is, for example, approximately 10 microns thick.

FIG. 8E shows the result of polishing oxide region 71 and depositing a silicon oxide region 78.

FIG. 8F shows the addition of a layer 80 and a layer 81. Layer 80 is composed of, for example, TiO₂, GeOx or SiGe. Layer 81 is composed of, for example, silicon dioxide. Layer 80 functions as an optical core and layers 78 and 81 function as cladding layers.

FIG. 8G shows a completed TIR element. A trench 101 has been etched through leaving the protective passivation coating 71 over resistor 82. A quartz cap 93 forms a liquid well 92. A quartz cap 93 forms a liquid well 92. Liquid enters and exits well 92 through a tube 95 and a tube 96. Tubes 95 and 96 allow liquid to easily fill well 92 and are used to control gas build up. Tubes 95 and 96 are used to regulate hot and cold fluid and are used to filtrate old liquid from well 92. An optional thermal electric cooler (TEC) 79 and an optional TEC 94 can be used for heating and cooling.

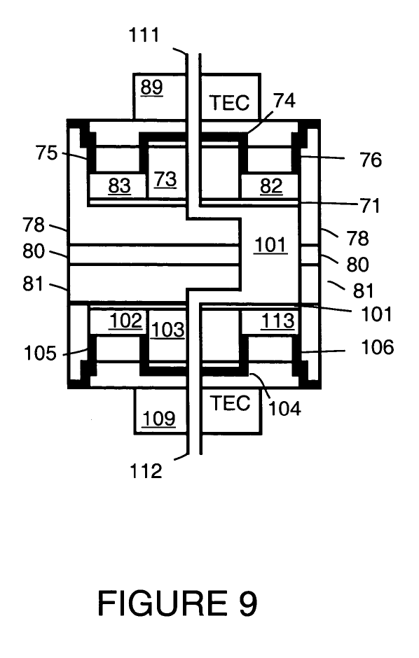

FIG. 9 shows another embodiment of a completed TIR element. A trench 101 is etched through leaving the protective passivation coating 71 over resistor 82. Another substrate is attached to layer 81, for example by wafer bonding. The substrate includes a logic region 102 and a resistor region 113. Connectors 104, 105 and 106 within oxide 103 are composed of, for example, tungsten. Liquid enters and exits trench 101 through a tube 111 and a tube 112 and optionally through additional tubes (not shown). Tubes 111 and 112 allow liquid to easily fill well trench 101 and are used to control gas build up. Tubes 111 and 112 are used to regulate hot and cold fluid and are used to filtrate old liquid from trench 101 as well as unwanted gases. An optional TEC 89 and an optional TEC 109 can be used for heating and cooling.

While FIGS. 8G and 9 show completed TIR elements, other opto-fluidic or bioanalysis devices can be formed from the arrangement shown in FIG. 8D where logic 83 and resistor 82 are formed in a same layer on substrate region 71. For example, a micro/nano designed reactor device or any device within the biofluidic realm can be formed where fluid is stored in a self-contained hermitically sealed package. One advantage of forming logic and resistor/heater devices in a same layer is that it makes practical a self-aligning process, such as that shown illustrated in FIGS. 8A through 8G. For example, when attaching layer 78 to layer 71, alignment is simplified because there are no intricate circuits to match up. After attaching layer 78 to layer 71, trenches, such as trench 91 can be located wherever heater regions (such as resistor 82) are located. This use of self-alignment significantly simplifies the manufacturing process. Similarly, this allows tubes 111 and 112 to be designed and scaled up to a higher fan out design for microfluidic or nanofluidic interconnects. The corresponding tube ends, for example, of hundreds to thousands of different micro/nanofluidic tubes can be interconnected into one chamber to study reactions with the aid of the integrated heater/coatings, hermetic purity and a optical waveguide. Similarly in a one to one interconnect to trench design large nano or micro print arrays can be built up for printing or bioapplications with a cover orifice layer replacing bonding of quartz cap 93 .

The foregoing discussion discloses and describes merely exemplary methods and embodiments of the present invention. As will be understood by those familiar with the art, the invention may be embodied in other specific forms without departing from the spirit or essential characteristics thereof. Accordingly, the disclosure of the present invention is intended to be illustrative, but not limiting, of the scope of the invention, which is set forth in the following claims.

1. An optical switch comprising:
single crystalline material forming fiber waveguides, the fiber waveguides being organized to form a plurality of intersections; and,
cladding material surrounding the fiber waveguide.

2. An optical switch as in claim 1 wherein a trench is located at each intersection in the plurality of intersections.

3. An optical switch as in claim 1 additionally comprising:
a plurality of heating segments, wherein a pair of heating segments from the plurality of heating segments are located at each intersection, each heating segment pair being electrically connected together through the single crystalline material at each intersection.

4. A opto-fluidic device comprising:
a substrate layer;
a logic and heater layer placed on a top of the substrate layer, the logic and heater layer including both a logic circuitry region and a heater region, the heater region including a resistor used as a heater; and,
liquid containment region located below the substrate layer, the liquid containment region including a trench that is situated below the heater region so that the heater can be used to heat liquid contained within the trench.

5. An opto-fluidic device as in claim 4, wherein the trench penetrates a fiber waveguide and cladding material surrounding the fiber waveguide.

6. An opto-fluidic device as in claim 4, additionally comprising:
at least one thermal electric heater.

7. An opto-fluidic device as in claim 4, wherein the opto-fluidic device is an optical switch.

8. An opto-fluidic device as in claim 4, wherein the opto-fluidic device is a total internal reflection switching element.

9. An opto-fluidic device as in claim 4, additionally comprising:
a second substrate layer below the liquid containment region; and,
a second logic and heater layer placed below the second substrate layer, the second logic and heater layer including both a second logic circuitry region and a second heater region, the second heater region including a second resistor used as a second heater;
wherein the trench is situated above the second heater region so that the second heater can be used to heat the liquid contained within the trench.

10. A device comprising:
a multilayer resistor, the multilayer resistor comprising:
a first layer composed of single crystalline material, and
man additional layer formed over the single crystalline material, wherein the first layer is physically and electrically connected to the additional layer.

11. A device as in claim 10, wherein the additional layer is a deposited layer.

12. A device as in claim 10, wherein the additional layer is formed from a substrate region bonded to the first layer.

13. A device as in claim 10, wherein the additionally layer is more chemically stable than the additional layer and the first layer is more thermally conductive than the first layer.

14. A device as in claim 10, wherein the additional layer is one layer in a multilayer stack of resistive materials.

15. A device as in claim 14, wherein the multilayer stack includes alternative layers of HfC and SiC.

16. A method for making an optical switch comprising:
forming fiber waveguides from a single crystalline material, the fiber waveguides being organized to form a plurality of intersections; and,
surrounding the fiber waveguide with cladding material.

17. A method as in claim 16 additionally comprising the following:
forming a trench at each intersection in the plurality of intersections.

18. A method as in claim 16 additionally comprising:
forming a plurality of heating segments, wherein a pair of heating segments from the plurality of heating segments are located at each intersection, each heating segment pair being electrically connected together through the single crystalline material at each intersection.

19. A method for forming an opto-fluidic device comprising:
placing a logic and heater layer on a top of a substrate layer, the logic and heater layer including both a logic circuitry region and a heater region, the heater region including a resistor used as a heater; and,
locating a liquid containment region below the substrate layer, the liquid containment region including a trench that is situated below the heater region so that the heater can be used to heat liquid contained within the trench.

20. A method as in claim 19 additionally comprising:
forming the trench within a fiber waveguide and cladding material surrounding the fiber waveguide.

21. A method as in claim 19 additionally comprising:
placing a second substrate layer below the liquid containment region;
forming a second logic and heater layer placed below the second substrate layer, the second logic and heater layer including both a second logic circuitry region and a second heater region, the second heater region including a second resistor used as a second heater; and,
situating the trench above the second heater region so that the second heater can be used to heat the liquid contained within the trench.

22. A method for forming a multilayer resistor, the multilayer resistor comprising:
forming a first layer composed of single crystalline material; and
forming an additional layer over the single crystalline material, so that the first layer is physically and electrically connected to the additional layer.

23. A method as in claim 22 wherein the additional layer is formed by deposition and etching.

24. A method as in claim 22 wherein the additional layer is formed by bonding a substrate region to the first layer.

25. A method as in claim 22 wherein the additionally layer is more chemically stable than the additional layer and the first layer is more thermally conductive than the first layer.

26. A method as in claim 22 wherein the additional layer is one layer in a multilayer stack of resistive materials.

27. A method as in claim 26 wherein the multilayer stack includes alternative layers of HfC and SiC.
